(19) United States
(12) Patent Application Publication
(10) Pub. No.: US 2024/0369601 A1
(43) Pub. Date: Nov. 7, 2024

(54) Fiber Optic Current Sensor Controller

(71) Applicant: Adam Jon Zbinden, Kenmore, WA (US)

(72) Inventor: Adam Jon Zbinden, Kenmore, WA (US)

(21) Appl. No.: 18/677,823

(22) Filed: May 29, 2024

(51) Int. Cl. G01R 15/24; G02F 1/01; G02F 1/03

(52) U.S. Cl. CPC G01R 15/24; G02F 1/0136; G02F 1/0305

(57) ABSTRACT

An optical fiber loop current sensing controller module, which integrates with the electrical power, and data processing and transmission, back-plane of a digital micro-processor relay for modular integration with the protection, metering, and communication functions of an electrical SCADA system. An optical transmitter is energized from a DC source on the digital relay, and emits unpolarized light of known intensity and wavelength to a linear polarizer, and the Stokes vector polarization parameters are calculated from the Mueller Matrix of the linear polarizer and the known intensity of the unpolarized optical input from the transmitter, which is then launched in alignment with the transmission axes of a polarization maintaining optical fiber link to a remote and passive fiber loop current sensor, where the linearly polarized optical pulse traverses a complete circular path around an energized conductor and experiences polarization state rotation in relation to the magnetic flux density which is proportional to current flow based on Ampere's law. The rotated polarized optical pulse is transmitted back to the optical fiber loop current sensing controller module via a return fiber optic cable, where the Stokes vector polarization parameters for the returned optical pulse having experienced Faraday rotation are calculated by splitting the pulse into four components, passing these components through a linear horizontal polarizer, a linear vertical polarizer, a linear polarizer with transmission axis set at 45 degrees, and a right circular polarizer comprised of a quarter wave plate connected to a linear polarizer with transmission axis set at 45 degrees, respectively, and where the four separate output channels of the four polarizing elements are then connected to be orthogonally incident a quadrature array of four separate photodetectors which transduce the optical intensity to electrical quantities, and the four optical receiver outputs connect to a digital data processing bus, where the Stokes vector parameters for the polarized optical pulse are calculated directly from the array of optical intensity values transduced by the photodetectors, and the change in polarization state is calculated by comparing the initial linear polarization Stokes vector parameters reference state transmitted to the remote fiber loop current sensor with the measured Stokes parameters of the rotated polarized optical pulse received back. This data is then converted to a calibrated current measurement, which is transmitted to a signal and data processing back plane of the digital micro processor relay via digital output ports on the optical current sensing controller module.

### BACKGROUND OF THE INVENTION:

Electrical current sensing is of primary importance in power delivery system supervisory control and data acquisition systems, hereby referred to as SCADA.

Accurate real-time monitoring of current levels in a power delivery system is necessary for two primary reasons:
1) The monitoring of normal power flows for metering purposes.
2) The monitoring of abnormal current flows which occur during fault conditions, for protection purposes.

Conventional electromagnetic current transformers suffer from several disadvantages, due to their galvanic coupling with the electric circuit. Electrical current transformers operate based on the mutual induction between a primary coil and a secondary coil, with the turns-ratio between primary and secondary determining the level of current transformation, inverse to the voltage transformation, due to constant power constraints.

Current Transformer saturation occurs when the magnitude of the current—and associated magnetic flux which couples with the secondary coil of the CT—exceeds the finite number of magnetic domains available in the mass of the iron core. When this occurs, as the AC current travels through a positive or negative half wave cycle, all magnetic domains within the iron core will align in the same direction before the AC current signal reaches a maximum or minimum amplitude. At this point, the secondary current will not accurately reproduce the primary current.

For faults occurring in medium voltage enclosed switchgear and indoor substations, there are high levels of available fault current, but space constraints limit the size of CTs used and thus the magnetic core becomes a limiting factor for sensor range, and saturation can occur under fault conditions, leading to sub-optimal protection element operation and limited post-facto event analysis.

Optical CTs, which exploit Faraday rotation of linearly polarized light due to the presence of a magnetic field when travelling within a waveguide transmission medium, can be used to measure electric current levels in a power distribution system, are galvanically isolated from the electrical system where current is being observed, and thus are immune to electrical fault failure modes. They also offer theoretically infinite bandwidth, as they do not use iron cores to store magnetic flux like conventional CTs. They also have a reduced mass and form factor for this reason. It is therefor desirable to provide a means of integrating optical CTs into power delivery SCADA systems via a digital relay sensor module interface, where an optical CT can convert its measurements into a sampled value from a standard communications format for transmission to the data-processing and communications backplane of modern digital relays. This also offers the advantage of providing a DC power source for the optical CT sensor controller directly from the digital relay it is interfaced with, requiring no additional auxiliary power sources. In an alternative embodiment, the DC power source may be provided by a battery or other energy storage element, and the digitally processed, Stokes parameter based, current calculations can be transmitted directly to an integrated display screen, for applications requiring a portable ammeter, such as long-term load studies.

While a modularized embodiment may interface directly with the back plane of a relay or programmable logic controller system installed in low and medium voltage switchgear for power distribution systems, the present invention will find applications in similar technologies, such as service panel metering and electric vehicle charging station SCADA systems. In this case, the method of securing the fiber loop sensor around the service conductors of interest will be considered as a separate mechanical design problem which is subject to the mechanical constraints of the application, and therefor considered as a separate device with an input and output in the context of the present invention, and U.S. Pat. No. 11,175,315B2 is referenced as an example of a passive remote fiber loop current sensor which is mechanically adapted to interface with an overhead power distribution system and provide current monitoring of overhead power transmission and distribution lines.

### SUMMARY OF THE INVENTION

The present invention provides a means of interfacing between a passive, remote, distributed optical current sensor, and digital micro-processor relays. The module can generate an optical pulse of known wavelength, where the Verdet constant of the fiber sensing loop is wavelength dependent, and of known optical intensity, which is then polarized linearly, to create an optical output of known Stokes polarization parameters, by determining the Stokes vector of the module output as the product of the Mueller matrix of the polarizer and the output signal intensity, to create a known and standardized input reference value for the Stokes polarization parameters at the input of the passive remote current sensor, and where the linear polarization state is maintained between the sensor controller output and the remote, passive sensor assembly with a polarization-maintaining fiber link between ports.

The linearly polarized optical pulse, with known Stokes vector polarization parameters based on the Mueller matrix of the polarizer and the intensity of the pulse emitted by the transmitter, reaches an input of the remote passive fiber loop sensor, and traverses a complete circular path around an electrically energized conductor and experiences polarization state rotation due to the magnetic flux resulting from the electron flux of the current.

The polarized optical pulse having undergone Faraday rotation then travels back to the sensor controller input, via a return fiber optic cable link, and enters a signal division state, where the linearly polarized optical pulse is divided into four outputs with equally rationed signal power, as can be accomplished with a two-stage cascade of optical splitters or other optomechanical methods including a 1:4 splitter as utilized in FTTx networks, where the insertion loss of the component is corrected for in the optical intensity measurement variable.

The four optical outputs with equally rationed signal power are transmitted separately through a linear horizontal polarizer, a linear vertical polarizer, a linear polarizer with its transmission axis set at 45 degrees, and a quarter waveplate connected to a linear polarizer with transmission axis set at 45 degrees. This creates four separate channels with different polarization states: Linear horizontal, linear vertical, linear at 45 degrees, and right circular.

The four polarized outputs are transmitted orthogonally incident to photodetectors to transduce the optical intensity into electrical quantities.

The intensities of these four polarization states are then used to calculate the Stokes vector polarization parameters of the polarized optical pulse received at the sensor controller from the output of the remote passive fiber loop sensor in a data processing bus within the electro-optical current sensing controller module.

The Stokes vector polarization parameters of the received polarized light which are measured with a four-channel polarimeter in this manner are compared with the known Stokes vector polarization parameters of the linearly polarized optical pulse input reference transmitted from the electro-optical current sensing controller module.

The difference in Stokes vector parameters characterizes the magnitude of Faraday rotation occurring in the remote fiber loop sensor, which directly correlates to magnetic field strength, and electron flux.

The transduced current data, in electrical form, is converted to a communications protocol which is compatible with the digital relay format and is transmitted to the data-processing and communications back plane of the digital relay for further utilization within the power system SCADA network.

### DESCRIPTION OF THE FIGURES

FIG. 1 is an embodiment of the present invention, depicting a DC power source 1 connecting to a device input power bus 2 which powers a solid state emitter 3 with calibrated wavelength and power levels which transmits through a linear polarizing element 4 and launches through a polarization maintaining fiber coupler output port 5 to an external passive fiber loop current sensor via a polarization maintaining launch cable, and returns to the device input port 6 via a fiber optic return cable from the output of the external fiber loop current sensor, where the input feeds directly to a 1:4 pulse division stage shown with 7, which outputs a quarter of the divided optical pulse to a linear horizontal polarizer 8, a linear vertical polarizer 9, a linear polarizer with transmission axis set at ±45° 10, and a right circular polarizer 11 comprised of a quarter waveplate retarder connected to a linear polarizer with transmission axis set at ±45°, respectively, with the output of each polarizing filter 8,9,10,11 connected to an orthogonally oriented photoreceiver 12 which electrically transduces the optical signal intensity to electrical current values, which are transmitted to a digital signal processing bus 13 which computes the Stokes polarization parameter vector for each optical pulse received from the input port 6, and computes the polarization rotation and proportional current values by comparing the calculated Stokes vector of the received optical pulse from input port 6 to the known Stokes vector of the polarization reference input value transmitted to an external fiber loop sensor from the polarization-maintaining fiber coupler output port 5, and the calculated current values are converted to a standard communications protocol format by the digital signal processing bus 13 and transmitted as sampled value digital outputs shown with 14.

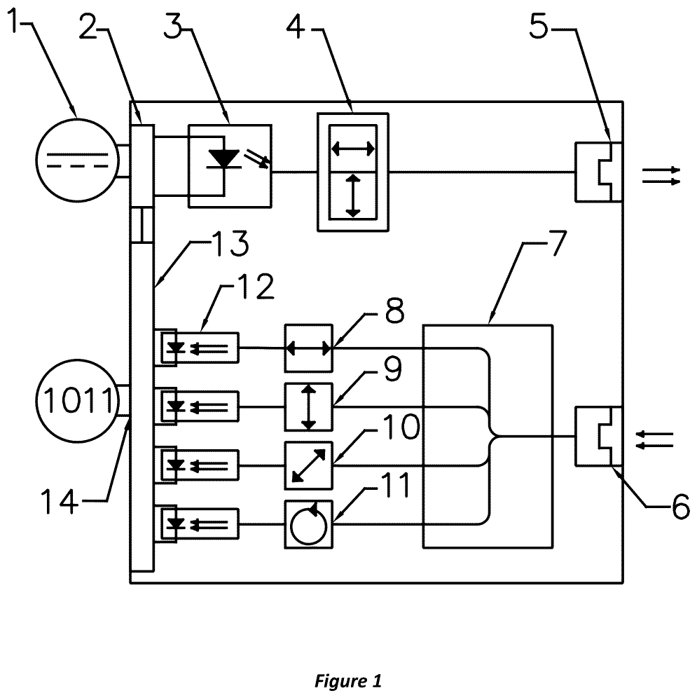

FIG. 2 depicts a flow-chart of the electro-optical current sensing process utilizing the Stokes vector polarization parameters.

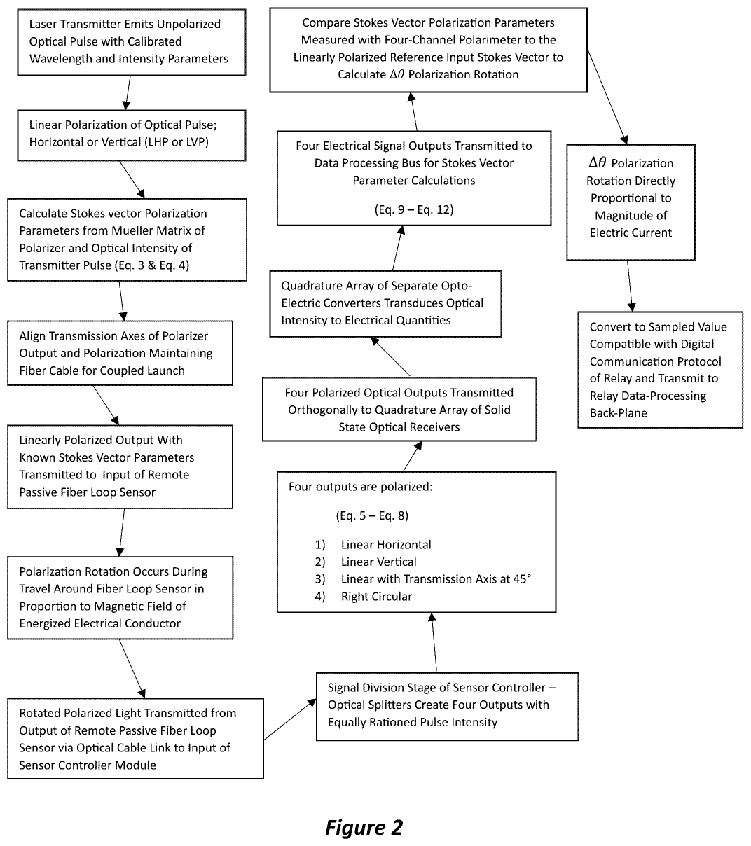

FIG. 3 is an embodiment of the present invention where a portion of the linearly polarized reference input signal, transmitted by the solid state emitter 3 and linear polarizing element 4, is split prior to launching through the PM fiber coupling output port 5 via a splitter shown with 16, and routed as feedback to a dedicated photoreceiver shown with 15 on the digital signal processing bus 13 which allows for real-time monitoring of the reference input power and intensity values.

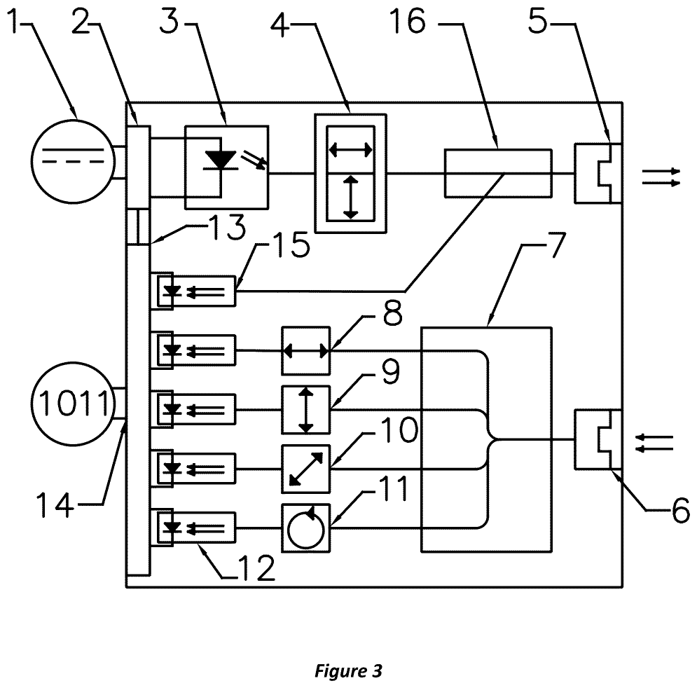

FIG. 4 presents a modular embodiment of the present invention for mobile current sensing applications, where the digital signal processing bus 13 outputs data directly to an integrated display screen 14 which is also powered by the input power bus 2 which is energized with a battery energy storage device 1 and where the device components are completely encased within a protective module shown with 17.

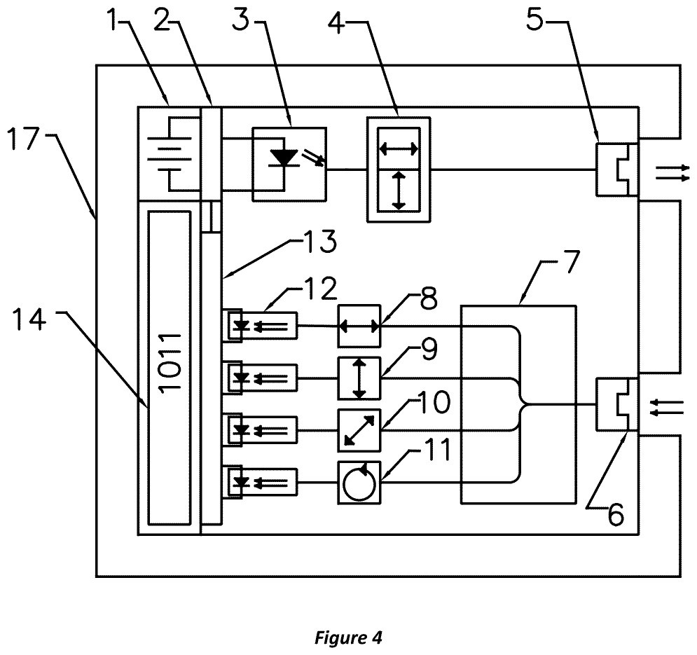

### DETAILED DESCRIPTION OF THE INVENTION

When linearly polarized light traveling in a waveguide transmission medium undergoes Faraday rotation in the presence of a magnetic field, the polarization state changes.

To measure the change, the Stokes polarization parameters, which completely describe the polarization state of light, are compared before and after traversing the passive fiber loop current sensor assembly, where the Stokes parameters (S) are defined in vector form as:

$$S = ( \begin{matrix}{S}_{0} \\ {S}_{1} \\ {S}_{2} \\ {S}_{3}\end{matrix} ) \qquad Eq . 1$$

Where S₀ is the overall intensity of the optical field generated by the polarized light pulse, S₁ is defined as the amount by which the intensity value of linearly horizontal polarized light exceeds the intensity value of linearly vertical polarized light present in the optical pulse, S₂ is the amount by which the intensity value of linearly positive 45 degree polarized light exceeds the intensity value of the linearly negative 45 degree polarized light, and S₃ is defined as the amount by which the intensity value of the right circularly polarized light exceeds the intensity value of the left circularly polarized light.

The passive remote sensor assembly input polarization state is linear, and the Stokes polarization vector for this reference input is calculated from the product of the optical signal intensity generated by the transmitter and the Mueller matrix of the linear polarizer, modulated by the amplitude transmission coefficient of the polarizer.

For a transmitter emitting unpolarized optical pulses, the Stokes vector is initially a known value, and the relation between the overall intensity of an optical pulse, as a function of polarization rotation state and phase displacement angle, and the four Stokes parameter observable intensity quantities, is expressed with the Stokes Intensity Equation as:

$$I ( θ , φ ) = \frac{1}{2} [ {S}_{0} + {S}_{1} cos 2 θ + {S}_{2} cos φsin2θ - {S}_{3} sin φsin2θ ] \qquad Eq . 2$$

The Stokes vector parameters for a linear horizontal polarization reference input which is transmitted to the remote fiber loop sensor are then calculated with:

$$( \begin{matrix}{{S}_{0}}^{′} \\ {{S}_{1}}^{′} \\ {{S}_{2}}^{′} \\ {{S}_{3}}^{′}\end{matrix} ) = \frac{{ρ}_{x}^{2}}{2} ( {S}_{0} + {S}_{1} ) ( \begin{matrix}1 \\ 1 \\ 0 \\ 0\end{matrix} ) \qquad Eq . 3$$

Where ρ is the amplitude transmission coefficient and is equal to 1 in an ideal polarizer, and S₀ and S₁ are known based on the output intensity of the unpolarized light source.

For a linear vertical polarization reference input, the Stokes vector describing the polarization parameters for the fiber loop sensor reference input value are found with:

$$( \begin{matrix}{{S}_{0}}^{′} \\ {{S}_{1}}^{′} \\ {{S}_{2}}^{′} \\ {{S}_{3}}^{′}\end{matrix} ) = \frac{{ρ}_{y}^{2}}{2} ( {S}_{0} - {S}_{1} ) ( \begin{matrix}1 \\ - 1 \\ 0 \\ 0\end{matrix} ) \qquad Eq . 4$$

Where ρ is the amplitude transmission coefficient and is equal to 1 in an ideal polarizer, and S₀ and S₁ are known based on the output intensity of the unpolarized light source.

The device then transmits linearly polarized optical pulses of known Stokes polarization parameters and is then configured to align with the transmission axes of polarization maintaining fiber at a PM launch coupling output, such that the optical fiber link between the sensor module output and the passive remote optic fiber loop sensor assembly input preserves the polarization state of the optical pulse injected to the input of the passive fiber loop current sensor assembly.

The optical pulse input to the remote passive sensor assembly in this manner then traverses a circular loop around an energized electrical conductor and returns to the sensor module input on a fiber link of negligible polarization mode dispersion, to negate pulse separation between the orthogonally polarized modes travelling from the passive fiber loop current sensor assembly to the sensing controller module input, and subsequent pulse-splitting stage, where the polarized optical pulse received from the remote fiber loop sensor is split in an equal 1:4 ratio, and the optical sub-components routed to four separate outputs.

The four optical outputs of the signal-division stage pass through polarizing elements again, before an orthogonally incident optoelectronic detector measures the intensity of each polarized optical output separately, in a quadrature array fashion.

A first quarter of the divided signal passes through a linear horizontal polarizer before reaching an optoelectronic detector to measure signal intensity, which is equal to:

$$I ( 0 , 0 ) = \frac{1}{2} ( {S}_{0} + {S}_{1} ) \qquad Eq . 5$$

A second quarter of the divided signal passes through a linear vertical polarizer before reaching an optoelectronic detector to measure signal intensity, which is equal to:

$$I ( \frac{π}{2} , 0 ) = \frac{1}{2} ( {S}_{0} - {S}_{1} ) \qquad Eq . 6$$

A third quarter of the divided signal passes through a linear polarizer with a transmission axis set at ±45 degrees before reaching an optoelectronic detector to measure signal intensity, which is equal to:

$$I ( \frac{π}{4} , 0 ) = \frac{1}{2} ( {S}_{0} + {S}_{2} ) \qquad Eq . 7$$

A fourth quarter of the divided signal passes through a right circular polarizer, comprised of a quarter waveplate connected to a linear polarizer with a transmission axis set at =45 degrees before reaching an optoelectronic detector to measure signal intensity, which is equal to:

$$I ( \frac{π}{4} , \frac{π}{2} ) = \frac{1}{2} ( {S}_{0} - {S}_{3} ) \qquad Eq . 8$$

And the Stokes vector polarization parameters are obtained as:

$${S}_{0} = I ( 0 , 0 ) + I ( \frac{π}{2} , 0 ) \qquad Eq . 9$$

$${S}_{1} = I ( 0 , 0 ) - I ( \frac{π}{2} , 0 ) \qquad Eq . 10$$

$${S}_{2} = 2 I ( \frac{π}{4} , 0 ) - {S}_{0} \qquad Eq . 11$$

$${S}_{3} = {S}_{0} - 2 I ( \frac{π}{4} , \frac{π}{2} ) \qquad Eq . 12$$

The Stokes Vector polarization parameters found with Eq. 9-12 are compared with the Stokes vector linear horizontal and linear vertical polarization state reference inputs to the passive sensor assembly, in Eq. 3 and Eq. 4.

The Δθ polarization state change experienced by the linearly polarized photon pulse traversing the passive fiber loop current sensor assembly is directly proportional to the strength of the magnetic field, β, based on Faraday rotation:

$$θ = V β l \qquad Eq . 13$$

Where V is the Verdet constant of the optical transmission medium of the fiber sensor and expresses the sensitivity to rotation in

$$\frac{rad}{T * m} ,$$

where the polarization state will rotate a certain amount of radians for a given magnetic flux density in Tesla which varies inversely with the distance from the magnetic field, and L is the effective path length traveled by the photon within the magnetic field.

The magnetic field strength, β, is then directly proportional to electrical current based on Ampere's Law:

$$∮ {\to }_{β} * {\to }_{dr} = {μ}_{0} {I}_{Encircled} \qquad Eq . 14$$

The four-way pulse division can be accomplished by cascading two stages of two-way beam splitters with 50:50 signal power rationing between the reflected and transmitted pulse output, to generate four optical pulses with equal power levels, or with a 1:4 FTTx signal splitter, where insertion losses are factored into the intensity state variable.

For the optical transmission network, the attenuation of the launch and receive cables which connect to the input and output ports of the electro-optical current sensing controller module, is a function of distance, and while polarization maintaining fiber links the optical current sensor controller module output and passive fiber loop current sensor assembly input so as to preserve the polarization parameters required for a stable linear polarization input state reference, which is required to calculate the change in polarization state resulting from the optical pulse traversing the fiber loop sensor assembly in the presence of the magnetic flux surrounding the electrically energized conductor, it is necessary to compensate for the distance attenuation, expressed in dB/km, of the launch cable. Absorption losses of components and connection losses are assumed to be measurable or known, such that the optical attenuation of the entire network on the transmit side which connects the electro-optical sensing controller module output to the passive fiber loop current sensor assembly input, and on the receive side, which connects the passive fiber loop current sensor assembly output to the electro-optical current sensing controller module input, can be accounted for and compensated in the measured intensity values at the four-channel polarimeter optoelectronic detector array, after beam-splitting occurs.

As maintaining a stable reference input polarization state seen at the distributed fiber loop sensor is critical for accurate Δθ polarization parameter measurements, the signal attenuation, in dB/Km, of the polarization maintaining launch cable which links the optical sensor controller transmitter output with the input of the remote, passive fiber loop sensor must be factored into the real signal intensity power level seen at the remote fiber sensor, and this actual value which accounts for the distance-based loss is subtracted from the transmitter output to estimate the true intensity value seen at the fiber loop sensor input when calculating the reference input Stokes vector polarization parameters.

The return fiber transmission cable which links the remote fiber loop sensor output with the optical current sensor controller input is required to have minimal polarization mode dispersion, to preserve the polarization state of optical pulses transmitted from the fiber loop sensor output, and the known distance-attenuation properties of the return fiber cable can be used to compensate for transmission and insertion losses in the optical sensing network.

The total optical power attenuation in the sensor controller and distributed fiber loop sensor network can be theoretically calculated based on the insertion loss values of all internal components and the length of the fiber optic launch and receive cables which link the sensor controller to the remote fiber sensor, and the intensity values used for Stokes vector polarization parameters are compensated accordingly, where the attenuation experienced by the optical signal pulse travelling from the controller module to the fiber loop sensor is subtracted from the initial reference input for linear polarization state based on known transmitter output intensity, while the attenuation of signal power, whether due to insertion losses, or distance, which occurs in the optical pulse as it travels from the remote fiber loop current sensor output to the optical current sensor controller module input is added to the to the intensity of the received optical pulse for compensation in the Stokes vector polarization parameter calculations.

In an alternative embodiment of the present invention, the DC input bus may be energized from a DC battery source, and the Stokes vector parameter calculations obtained from the received detector intensities and resulting polarization rotation current calculations may be routed from the digital outputs of the digital data processing bus directly to an LCD or LED display screen on the fiber optic current sensor controller module, for portable ammeter and mobile power quality survey applications. The input and output ports may interface with the fiber loop current sensor with launch and receive cables, as in optical time domain reflectometry and optical loss test devices, or the fiber loop sensor may directly interface with the input and output ports of the fiber optic current sensor controller.

The light source and detector used for the transmitter and detector can be solid state devices. The emitter power level and wavelength is assumed to be controllable and stable. The polarization control of the photonic circuit may be accomplished with macro-optic components, such as polarizing lenses and waveplates, or with flexible single mode fiber optic cables, where birefringent axes are created and rotated within the fiber with mechanical force, and micro pressure induces controllable phase retardance, such that both polarization and phase retardance of the fiber optic cable is controllable, when it is mechanically twisted to create stress-induced birefringence of controlled rotation angle based on the physical rotation of the slow and fast polarization axes within the fiber itself, which is also acting as a polarizing waveplate in proportion to applied pressure, in the case of a circular polarization output, or a linear polarizing filter, which can be utilized to create the linear polarization reference input to a passive fiber sensor, or to apply the polarization filters to the four-way divided pulse received from a sensor output and which contains transduced magnetic flux data from which the current level is directly calculated by integration from Ampere's law, wherein the four Stoke's parameters are calculated by measuring the intensity of the rotated polarized optical pulse at the four observable conditions of polarization rotation angle and phase delay required to completely solve the Stoke's intensity equation for all four observable intensity parameters which when superimposed completely characterize the state of optical polarization. The ability to simultaneously measure all four Stoke's parameters for a single optical pulse and solve the intensity equation with superposition is due to pulse splitting, where the optical pulse's modal field power distributes equally to four different output channels, at which point the polarization control and filtering required to perform classical Stoke's parameter characterization by measuring the intensity of the sampled light being analyzed at the four polarization rotation and phase delay conditions necessary to completely solve the Stoke's intensity equation for all four Stoke's observable parameters, and the ability to quantify the intensity, with both high resolution and numerical precision, using solid state photoreceivers, which can provide an output diode current which is proportional to the received photon flux input power, enables precise relative current fluctuation measurements to be recorded with high sampling frequency. The use of flexible fiber components with mechanically induced birefringence and controlled transmission axis rotation angle, to perform polarization control in the photonic measurement circuit, may be useful in the embodiment of the present invention where a portable current sensing module enables mobile current sensing of energized conductors for ammeter applications in the field, where an advantage of said invention embodiment over existing portable sensing methods in the art field of portable ammeters is the extended optical launch and receive patch cords which interface between a fiber loop sensor which surrounds an electrically energized conductor, and the optical current sensing module being held by a user, where said patch cables allow a user to stand remote from an energized conductor being surveyed optically for current data at a distance which is compliant with arc flash incident energy safety requirements.

In another embodiment of the present invention, the photonic circuit for measuring current may be implemented as a photonic integrated circuit, such as when modularly interfacing with a digital relay, where a polarizing fiber laser output can perform the function of the emitter and linear polarizer output, and waveplate polarizers on a silicone substrate can implement the photonic measurement circuit topology which connects with integrated solid-state photoreceivers connected to the digital processing bus.

1: A photonic circuit for measuring electrical current, configured to integrate with the electrical power and data processing back-plane of a digital micro-processor relay, which interfaces with a passive fiber loop current sensor, comprising:
an optical transmitter, connected to the electrical power back-plane of said digital relay with a module input power bus, capable of emitting unpolarized optical pulses of controlled intensity and wavelength;
a linear polarizer, with an input coupled to an output of said transmitter, where said linear polarizer features an output;
a module output coupler, which optomechanically aligns a transmission axis of said linear polarizer output to launch in alignment with a transmission axis of a polarization maintaining fiber link;
a module input coupler, which mates with a fiber optic cable to receive rotated polarized optical pulses from a remote passive fiber loop current sensor;
a pulse-splitting stage, connected to said module input, which is capable of emitting four optical output pulses, with equally rationed pulse intensity at four separate optical output channels of said pulse-splitting stage;
a linear horizontal polarizer, with an input connected to a first output of the pulse-splitting stage, and an output connected to an optoelectronic receiver configured orthogonally to an incident pulse from said polarizer output which electrically transduces the optical pulse intensity;
a linear vertical polarizer, with an input connected to a second output of the pulse-splitting stage, and an output connected to an optoelectronic receiver configured orthogonally to an incident pulse from said polarizer output which electrically transduces the optical pulse intensity;
a linear polarizer with transmission axis set to 45 degrees, with an input connected to a third output of the pulse-splitting stage, and an output connected to an optoelectronic receiver configured orthogonally to an incident pulse from said polarizer output which electrically transduces the optical pulse intensity;
a right circular polarizer, comprised of a quarter-waveplate connected to a linear polarizer with transmission axis set to 45 degrees, with an input connected to a fourth output of the pulse-splitting stage, and an output connected to an optoelectronic receiver configured orthogonally to an incident pulse from said polarizer output which electrically transduces the optical pulse intensity;
a digital data processing bus, connected to the module input power bus, which receives an array of four separate outputs from said optoelectronic receivers, and which calculates the Stokes polarization vector for the optical pulse from said array of four separate measured optical pulse intensities simultaneously generated by the optoelectronic detector array, which is capable of converting data into a standard communication protocol format; and,
digital outputs from the data processing bus, which are connected to the data-processing back-plane of the digital relay which the optical current sensing controller module is integrated with.

2: A photonic circuit for measuring electrical current as in claim 1, wherein the output of the optical transmitter and linear polarizer is split prior to reaching the module output coupler, and a portion of the linearly polarized light output is provided as feedback to a dedicated photo-detector input connected to the digital data processing bus, which enables constant real-time monitoring of the optical reference input intensity value and Stokes parameters.

3: A portable optical current sensing module, which contains a photonic circuit for measuring electrical current, which interfaces with a passive fiber loop current sensor for mobile current metering applications, comprising:
an optical transmitter, energized with a module input power bus connected to an electrical energy storage device, capable of emitting unpolarized optical pulses of calibrated intensity and wavelength;
a linear polarizer, with an input coupled to an output of said transmitter, where said linear polarizer features an output;
a module output coupler, which optomechanically aligns a transmission axis of said linear polarizer output to launch in alignment with a transmission axis of a polarization maintaining fiber link;
a module input coupler, which mates with a fiber optic cable to receive rotated polarized optical pulses from a passive fiber loop current sensor;
a pulse-splitting stage, connected to said module input, which is capable of emitting four optical output pulses, with equally rationed pulse intensity at four separate optical output channels of said pulse-splitting stage;
a linear horizontal polarizer, with an input connected to a first output of the pulse-splitting stage, and an output connected to an optoelectronic receiver configured orthogonally to an incident pulse from said polarizer output which electrically transduces the optical pulse intensity;
a linear vertical polarizer, with an input connected to a second output of the pulse-splitting stage, and an output connected to an optoelectronic receiver configured orthogonally to an incident pulse from said polarizer output which electrically transduces the optical pulse intensity;
a linear polarizer with transmission axis set to 45 degrees, with an input connected to a third output of the pulse-splitting stage, and an output connected to an optoelectronic receiver configured orthogonally to an incident pulse from said polarizer output which electrically transduces the optical pulse intensity;
a right circular polarizer, comprised of a quarter-waveplate connected to a linear polarizer with transmission axis set to 45 degrees, with an input connected to a fourth output of the pulse-splitting stage, and an output connected to an optoelectronic receiver configured orthogonally to an incident pulse from said polarizer output which electrically transduces the optical pulse intensity;
a digital data processing bus, connected to the module input power bus, which receives an array of four separate outputs from said optoelectronic receivers, and which calculates the Stokes polarization vector for the optical pulse from said array of four separate measured optical pulse intensities simultaneously generated by the optoelectronic detector array, and which calculates a current magnitude based on the measured polarization rotation; and,
an integrated display screen on the module, connected to the module input power bus, which shows electrical current magnitude.
